(19) United States
(12) Patent Application Publication
(10) Pub. No.: US 2009/0188626 A1
(43) Pub. Date: Jul. 30, 2009

(54) PLASMA JET DEVICE

(76) Inventors: Xinpei LU, Wuhan (CN); Yuan PAN, Wuhan (CN)

Correspondence Address: MATTHIAS SCHOLL, 14781 MEMORIAL DRIVE, SUITE 1319, HOUSTON, TX, 77079, US

(21) Appl. No.: 12/256,593

(22) Filed: Oct. 23, 2008

(30) Foreign Application Priority Data
Jan. 25, 2008 (CN) 200810046795.4

(51) Int. Cl. C23C 16/513; C23F 1/02

(52) U.S. Cl. 156/345.35; 118/723 R

(57) ABSTRACT

A plasma jet device, comprising a dielectric container comprising a gas inlet and a plasma jet outlet, and an electrode. The electrode, which is completely covered by dielectric material, is inserted into the dielectric container and connected to the power supply. The dielectric material is in the form of a hollow tube with one end closed and another end opened. The power supply is connected to the electrode from the open end of the dielectric material. The dielectric material can also be a coated dielectric layer, which covers the electrode completely except one end for connecting to the power supply. A grounding electrode can be added downstream, outside the dielectric container or the nozzle. There also can be multiple electrodes inside the dielectric container arranged in a row or multiple rows, or in the shape of a circle or disk.

### CROSS-REFERENCE TO RELATED APPLICATIONS

This application claims priority benefits to Chinese Patent Application No. 200810046795.4 filed Jan. 25, 2008, the contents of which, including any intervening amendments thereto, are incorporated herein by reference.

### BACKGROUND OF THE INVENTION

1. Field of the Invention

The present invention relates to a plasma jet device.

2. Description of the Related Art

Non-equilibrium plasmas have recently attracted a great amount of attention. Typically, plasma consists of ions, neutral species and electrons. In general, plasmas may be classified into thermal equilibrium and thermal non-equilibrium plasmas. Thermal equilibrium implies that the temperatures of all species including ions, neutral species, and electrons, are equal.

Plasmas may also be classified into local thermal equilibrium (LTE) and non-LET plasmas. The term “local thermal equilibrium (LTE)” refers to a thermodynamic state where the temperatures of all the plasma species are equal in localized areas of plasma.

In non-LTE plasmas, or simply non-thermal plasmas, the temperature of the ions and the neutral species is usually much lower than that of the electrons. Therefore, non-LTE plasma may serve as highly reactive media for applications where temperature sensitive material is treated. This “hot coolness” allows a variety of processing possibilities and economic opportunities for various applications, including plasma deposition and plasma plating, etching, surface treatment, chemical decontamination, biological decontamination, and medical applications.

At one atmospheric pressure, due to the relative high breakdown voltage of working gases, the discharge gaps are normally from a few millimeters to several centimeters in range limiting the size of objects that can be treated directly. If indirect treatment (remote exposure) is used, certain short lifetime active species, such as oxygen atom, charge particles may already disappear before reaching the object to be treated, which makes the efficiency of treatment much lower.

To address these concerns, non-equilibrium atmospheric pressure plasma jet devices have recently been attracting significant attentions. The plasma jet devices generate plasma plumes in open space (surrounding air) rather than in confined discharge gaps only. Thus, they can be used for direct treatment and there is no limitation on the size of the objects to be treated.

Examples of conventional atmospheric pressure non-equilibrium plasma jet devices include: AC, RF, Microwave, and Pulsed DC Non-equilibrium plasma jet devices. Each of these devices is briefly described below.

AC Non-Equilibrium Plasma Jet Device

Recently, Y. Hong et al. reported an AC non-equilibrium plasma jet device with nitrogen as working gas (“Microplasma Jet at Atmospheric Pressure” Appl. Physics Letters 89, 221504 (2006). The device consists of an electrode 3, a grounding electrode 16, two centrally perforated dielectric disks 14, a dielectric container 4 and an alternating current (AC) power supply 1. The power supply 1 is connected to the electrode 3 and the grounding electrode 16. Both electrodes are perforated with a hole of 500 μm diameter, which serve as the plasma jet outlet 11. Both the electrode 3 and the grounding electrode 16 are made of an aluminum disk having a 20 mm diameter and 3 mm thickness attached to the surface of the centrally perforated dielectric disks 14 which has the same diameter with the electrode 3 and the grounding electrode 16. The electrode 3, the grounding electrode 16 and the dielectric disks 14 are inserted in the dielectric container 4 of the same diameter as that of the dielectric disks 14 and the dielectric container 4 is in form of a hollow cylinder with two open ends, as shown in FIG. 1. Once the working gas (nitrogen) 6 is introduced through the aligned holes of the electrode 3, the grounding electrode 16 and the dielectric disks 14, and AC high voltage is applied, a discharge is fired in the gap between the electrode 3 and the grounding electrode 16, and a long plasma jet 10 reaching a length up to 6.5 cm is ejected to the open air through the plasma jet outlet 11. Because the electrode 3 and the grounding electrode 16 are contacted with the plasma jet 10 directly, this leads to discharge arc being formed easily when applying high voltage and is not safe for applications such as tooth cleaning, root canal disinfection, and acceleration of wound healing.

A similar AC non-equilibrium plasma jet device is described by Zhang et al. (“A novel cold plasma jet generated by atmospheric dielectric barrier capillary discharge” Thin Solid Films 506 (2007)). As shown in FIG. 2, the device comprises an electrode 3, a grounding electrode 16, a dielectric container 4, a flow controller 8 and an alternating current (AC) power supply 1. The electrode 3 is made of tungsten placed in the center of the dielectric container 4 and is connected to the power supply 1. The grounding electrode 16 is placed on the outside wall of the dielectric container 4. By adjusting the flow controller 8 the flow rate of the working gas 6 is controlled, which is injected into the dielectric container 4 through the gas inlet 7. When the AC voltage is applied, plasma jet 10 is generated. The main disadvantage of this device is that the electrode 3 is directly contacted with the plasma jet 10, which is also not safe in certain applications.

RF Non-Equilibrium Plasma Jet Device

A RF non-equilibrium plasma jet device was recently described by Stoffels et al., (“Plasma Needle for in vivo Medical Treatment: Recent Developments and Perspectives” Plasma Sources Sci. Technol. 15 (2006)). As shown in FIG. 3, the device comprised an electrode 3, a dielectric container 4, a dielectric material 5 (a ceramic tube) and a radio frequency (RF) power supply 1 connected with the electrode 3. The electrode 3 is made of tungsten having a diameter of 0.3 mm placed in the center of the dielectric material 5 having a diameter of 4 mm, which is attached to a fixed-mount 13. The right end of the electrode 3 is not covered by the dielectric material 5. Working gas (helium) 6 flows into the dielectric container 4 through a gas inlet 7 at a flow rate of about 2 L/min. The device is driven by an RF power supply with frequency of about 10 MHz. The size of the generated plasma is about 2.5 mm. One of the disadvantages of this device is that the end of the electrode 3 is not covered by the dielectric material 5. Therefore, the electrode 3 is directly contacting with plasma, which is not safe for certain applications. Besides, the length of the plasma jet 10 is very short. When the applied power is 3 W, the temperature of the plasma jet 10 is about 90° C. and 50° C. at 1.5 mm and 2.5 mm from the electrode 3, respectively.

Microwave Non-Equilibrium Plasma Jet Device

In recently years, several new microwave plasma jet devices have been developed. However, the gas temperature of the plasma generated by most of these devices are relatively high, i.e., at least several hundred degrees, which limits their applications for the treatment of temperature sensitive objects.

Pulsed DC Non-Equilibrium Plasma Jet Device

A pulsed plasma jet called “plasma pencil,” which was developed by XinPei Lu et al. (“Dynamics of an atmospheric pressure plasma generated by submicrosecond voltage pulses” J. Appl. Phys. 100, 063302 (2006)). As shown in FIG. 4, the device comprises an electrode 3, a grounding electrode 16, and a dielectric container 4, two dielectric disks 14, a ring 15 and a pulsed direct current voltage (Pulsed DC) power supply 1 connected with the electrode 3 and the grounding electrode 16. The electrode 3 and the grounding electrode 16 both are made of copper ring with the same diameter of about 2.5 cm and attached to the surface of the centrally perforated dielectric disks 14. A ring 15 is placed between the two dielectric disks 14 and the electrode 3. The grounding electrode 16, the two dielectric disks 14, and the ring 15 are inserted in the front space of the dielectric container 4, and are arranged in a coaxial configuration. When submicrosecond high voltage pulses (up to 10 kV) at repetition rates in the 1-10 kHz range are applied to the two electrodes through which working gas 6 (He or He/O₂) is injected with a flow rate of 2-5 L/min, a plasma jet 10 of up to 5 cm is generated in the surrounding air. One of the disadvantages of this device is that arc discharge between the electrode 3 and the grounding electrode 16 can occur directly under certain conditions, such as when the pulse width is larger than 10 μs.

As above mentioned, most of the conventional plasma jet devices have disadvantages. Similar problems also exist for some recently patented plasma jet generating methods, apparatuses and systems. See e.g., U.S. Pat. No. 5,198,724 for “Plasma Processing Method and Plasma Generating Device” issued Mar. 20, 1993, U.S. Pat. No. 5,369,336 for “Plasma Generating Device” issued Nov. 29, 1994, both to Koinuma et al., U.S. Pat. No. 5,961,772 for “Atmospheric-pressure plasma jet” issued Oct. 5, 1999, and U.S. Pat. No. 6,262,523 for “Large area atmospheric-pressure plasma jet” issued Jul. 17, 2001, both to Gary S. Selwyn et al. These disadvantags limit the widely the use of the non-equilibrium plasmas in various applications.

### SUMMARY OF THE INVENTION

This invention provides a plasma jet device, aiming at generating large length, low temperature plasma jet rich with active species at an atmospheric pressure. The temperature of the generated plasma jet is close to room-temperature; the electrodes are placed safely; and the device is able to utilize various working gases.

The plasma jet device comprises a dielectric container with a gas inlet and a plasma jet outlet, and an electrode. The electrode is completely covered by dielectric material and is inserted into the dielectric container and connected to a power supply.

In certain classes of this embodiment or in other embodiments of the invention, the dielectric material is a hollow tube with one end closed and another end opened. The electrode is inserted into the hollow tube and connected to the power supply at the open end.

In certain classes of this embodiment or in other embodiments of the invention, the dielectric material is a coated dielectric layer, which covers the electrode completely except at the end connected to the power supply.

In certain classes of this embodiment or in other embodiments of the invention, the dielectric material is a hollow sheath with one end closed and another end opened. The electrode is inserted into the hollow sheath and connected to the power supply at the open end.

In certain classes of this embodiment or in other embodiments of the invention, a grounding electrode is added to the downstream outside the dielectric container or the nozzle.

In certain classes of this embodiment or in other embodiments of the invention, there are multiple electrodes inside the dielectric container.

In certain classes of this embodiment or in other embodiments of the invention, the multiple electrodes inside the dielectric container are arranged in a single row or in multiple rows.

In certain classes of this embodiment or in other embodiments of the invention, the multiple electrodes inside the dielectric container are arranged in the form of a circle.

In certain classes of this embodiment or in other embodiments of the invention, the multiple electrodes inside the dielectric container are arranged in the form of a disk.

In certain classes of this embodiment or in other embodiments of the invention, the radial-section of the plasma jet outlet and the nozzle includes a circle, an ellipse, a racetrack shape, a rectangle, a polygon, or combinations thereof.

In certain classes of this embodiment or in other embodiments of the invention, the electrode is in form of a thread, a rod, or a sheet.

In certain classes of this embodiment or in other embodiments of the invention, the hollow tube has single through-pass hole with one end closed and another end opened.

In certain classes of this embodiment or in other embodiments of the invention, the hollow tube has multiple through-pass holes with one end closed and another end opened.

The advantages of the invention include the following.

(1) The electrodes are covered completely by the dielectric material, and are inserted into the dielectric container together, which insulates the electrodes from directly contacting the plasma. Therefore, not only is the possibility of arc discharge completely avoided, but also the device is made safe for any applications.

(2) The working gases, including helium, oxygen, argon, nitrogen, mixture gas, air, gaseous compounds and gaseous organic compounds, can be used.

(3) Plasma jet can reach more than 10 cm in length.

(4) The cross-section of the plasma can be small or big.

(5) The gas temperature of the plasma can be as low as room temperature.

(6) The device is portable, safe, easy to operate, and low cost.

(7) The device can be used for various applications such as etching, deposition, surface processing, cleaning, decontamination, food processing, tooth cleaning, and root canal disinfection.

(8) The plasma jet generated by this device can have different length, geometric shape, gas temperature and various active species.

(9) The device can generate large-scale and large-area plasmas by using various configurations.

(10) The plasma jet generated by this present invention belongs to non-equilibrium low temperature plasma, which further expands the applications of low temperature plasma and improves its efficacy.

### BRIEF DESCRIPTION OF THE DRAWINGS

The invention is described hereinbelow with reference to accompanying drawings, in which:

FIG. 1 is a perspective view of a conventional AC non-equilibrium plasma jet device;

FIG. 2 is a perspective view of another conventional AC non-equilibrium plasma jet device;

FIG. 3 is a perspective view of a conventional RF plasma needle;

FIG. 4 is a perspective view of a conventional pulsed DC plasma pencil;

FIG. 5 is a perspective view of a first embodiment of the present invention;

FIG. 6 is a perspective view of a second embodiment of the present invention;

FIG. 7 is a perspective view of a third embodiment of the present invention;

FIGS. 8(a)-(b) are cross-sectional views of a dielectric tube shown in the embodiment illustrated in FIG. 7;

FIG. 9 is a perspective view of a fourth embodiment of the present invention;

FIGS. 10(a)-(b) are cross-sectional views of alternative embodiments of the fixed-mount shown in FIG. 7 and FIG. 9;

FIG. 11(a) is a perspective view of a fifth embodiment of the present invention with the electrode in form of a hackle-sheet;

FIG. 11(b) is a cross-section view along line A-A in FIG. 11(A) of a fifth embodiment of the present invention;

FIG. 12(a) is an elevation-view of a rectangle-sheet electrode;

FIG. 12(b) is a side-view of a rectangle-sheet electrode;

FIGS. 13(a)-(b) are cross-section views of alternative embodiments of the nozzle shown in FIGS. 6, 7, and 11.

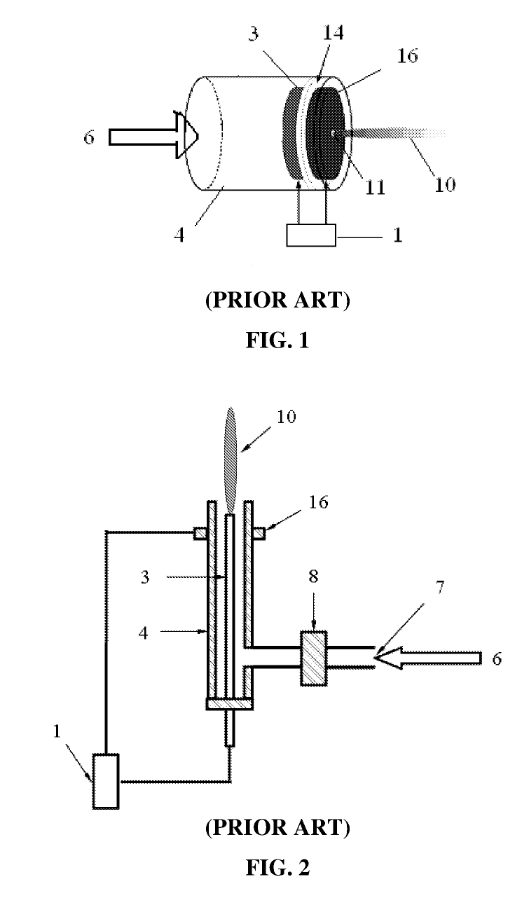

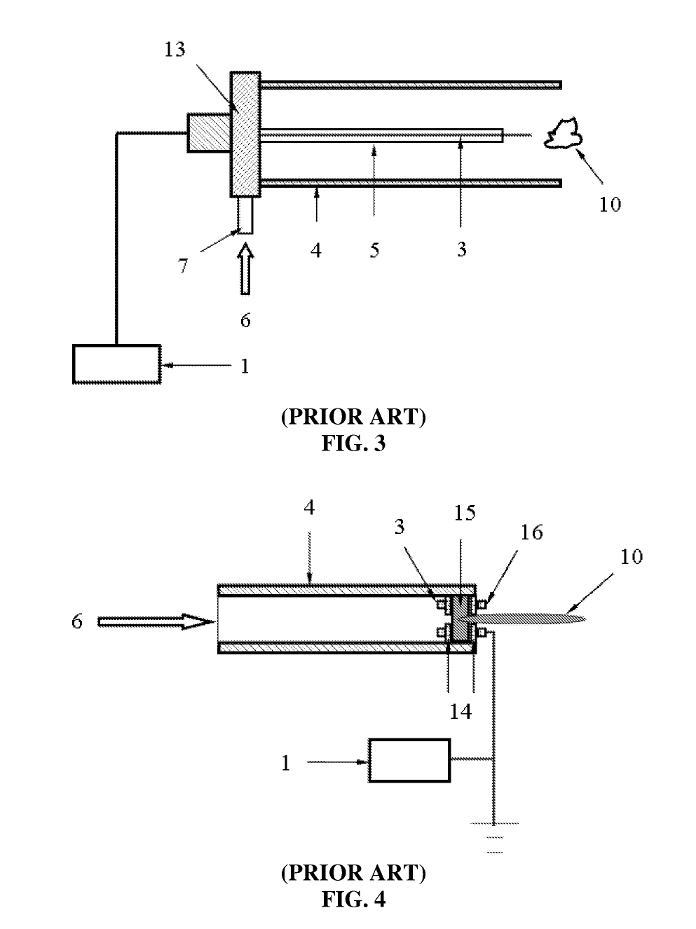

### DETAILED DESCRIPTION OF THE INVENTION

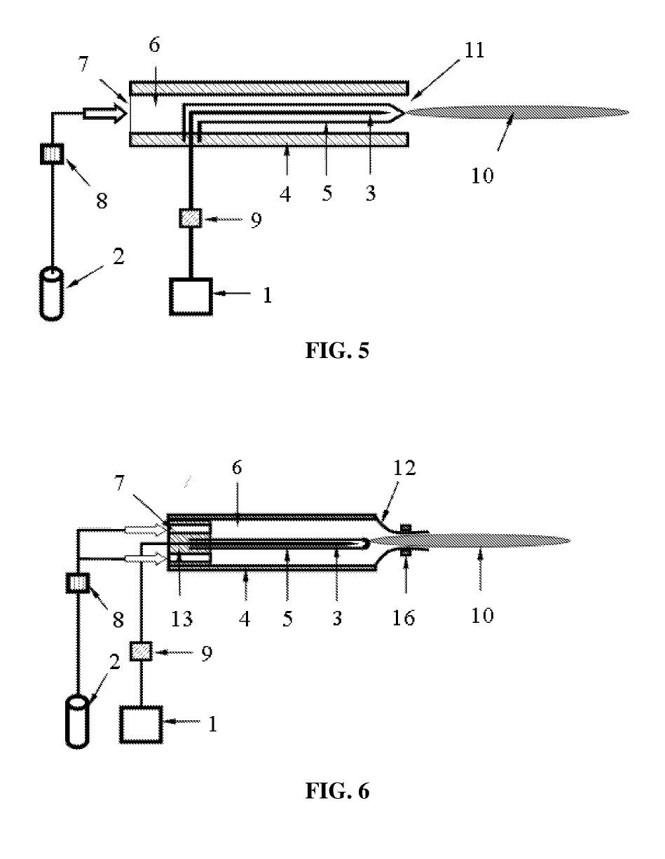

With reference to FIG. 5, a plasma jet device in accordance with a first embodiment of the present invention will be explained. The device comprises a gas supply 2, a power supply 1, an electrode 3, a dielectric container 4 and a flow controller 8. The electrode 3, which is completely covered by the dielectric material 5, is inserted into the dielectric container 4 and connected to the power supply 1 through a power controller 9. The dielectric material 5 is in the form of a bent hollow tube with one end closed and another end opened, which is fixed inside the dielectric container 4. The top closed end of the dielectric material 5 has a pyramidal geometry. By controlling the flow controller 8, the flow rate of the working gas 6 injected into the dielectric container 4 through the gas inlet 7 is adjusted. The generated plasma jet 10 is ejected out of the plasma jet outlet 11.

FIG. 6 is a perspective view of a second embodiment of the present invention. The device comprises a gas supply 2, a power supply 1, an electrode 3, a dielectric container 4, a flow controller 8, a nozzle 12, and a grounding electrode 16 covering outside of the nozzle 12. The electrode 3, which is completely covered by the dielectric material 5, is inserted into the dielectric container 4 and connected to the power supply 1 through a power controller 9. The dielectric material 5 is in form a hollow sheath with one end closed and another end opened, which is fixed inside the dielectric container 4 by the fixed-mount 13. There are two gas inlets 7 inside the fixed-mount 13, from the two gas inlets 7 the working gas 6 is injected into the dielectric container 4 uniformly. The plasma jet 10 is generated when the device operated.

The dielectric material 5 is a dielectric sheath with a spheriform end, where the open end is interposed fixedly into the fixed-mount 13. The electrode 3 is in the form of a rod-like conductor with a spiculate end. The nozzle 12 with a roundness radial-section connects with the downstream end of the dielectric container 4.

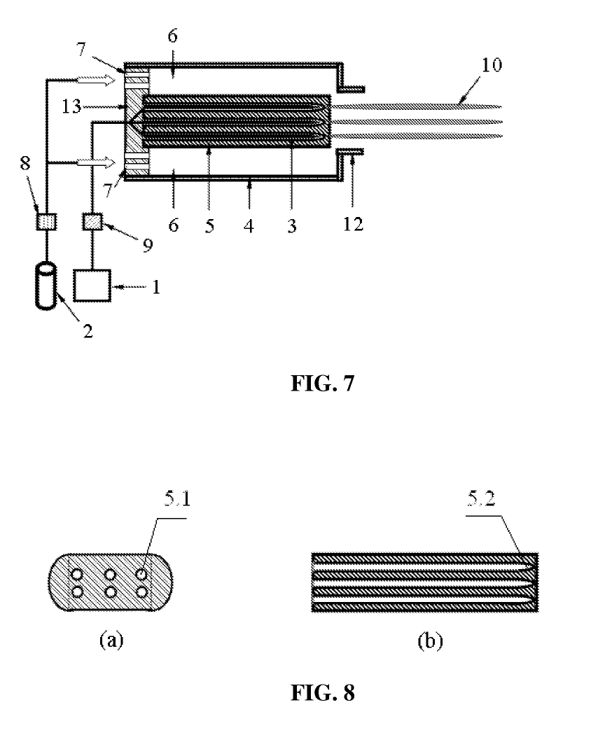

FIG. 7 is a perspective view of a third embodiment of the present invention with multiple electrodes inside the dielectric container, comprising a gas supply 2, a power supply 1, multiple electrodes 3, a dielectric container 4, and a nozzle 12. The multiple electrodes 3, which are completely covered by the dielectric material 5, are inserted into the dielectric container 4 and connected to the power supply 1 through a power controller 9. The dielectric material 5 is in the form of a tube with multiple rows of holes with one end closed and another end opened, which is fixed inside the dielectric container 4 by the fixed-mount 13. The flow rate of the working gas 6 injected into the dielectric container 4 from the gas inlets 7 is adjusted by the flow controller 8. The plasma jet 10 is generated when the device is operated.

FIGS. 8(a)-(b) illustrate cross-sectional views of a dielectric tube with six holes in two rows shown in the embodiment of FIG. 7, where the radial-section of the holes is a circle and the top of the holes is in the shape of a tip-sphere.

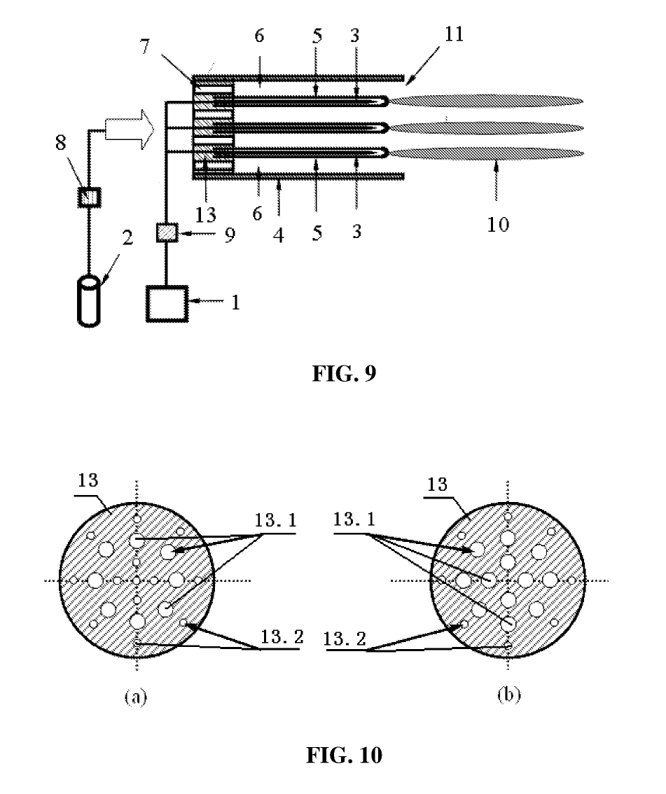

In order to generate multiple plasma jets, there are single row or multiple rows of holes 5.1 inside the dielectric material 5 (tube or sheath), and multiple electrodes 3 are placed inside the holes respectively. The number of holes and the number of rows are adjusted according to the actual requirements of applications for which the device is used, and there are two rows of six holes in a third embodiment of the present invention of FIG. 7. Alternatively, through the fixed-mount 13 with multiple fastness holes, multiple individual integrals of electrode 3 covered completely inside the dielectric material 5 (tube or sheathe) are fixed inside the dielectric container 4, as illustrated in a fourth embodiment of the invention shown in FIG. 9. In addition, the various manners and geometries of arrangement of the multiple electrode inside the dielectric container are adjusted in accordance with the requirements of actual applications in which the devices are to be used.

FIG. 9 is a perspective view of a fourth embodiment of the present invention with multiple electrodes inside the dielectric container, comprising a gas supply 2, a power supply 1, multiple electrodes 3, a dielectric container 4, and a flow controller 8. The multiple electrodes 3, which are completely covered by the dielectric materials 5 respectively, are inserted into the dielectric container 4 and connected to the power supply 1 through a power controller 9. The dielectric materials 5 are in the form of a hollow tube with one end closed and another end opened, which are fixed inside the dielectric container 4 by means of the fixed-mount 13. The flow rate of the working gas 6 injected into the dielectric container 4 from the gas inlets 7 is adjusted by the flow controller 8. The generated plasma jets 10 ejects out of the plasma jet outlet 11.

FIG. 10(a) is a perspective view of a fixed-mount enabling the multiple electrodes to be arranged in the form of a circle. FIG. 10(b) is a perspective view of a fixed-mount enabling the multiple electrodes to be arranged in the form of two circles or a disk. There are fastener holes 13.1 and blowholes 13.2 disposed inside the fixed-mount 13. The blowholes 13.2 enable the working gas 6 to be injected into the dielectric container uniformly.

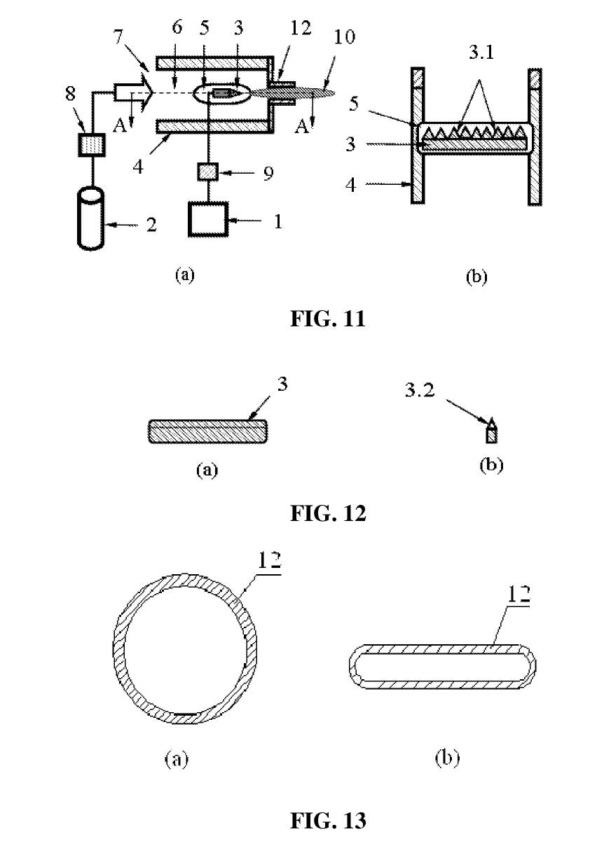

FIG. 11(a) is a perspective view of a fifth embodiment of the present invention with the electrode in form of a hackle-sheet, the device comprising a gas supply 2, a power supply 1, an electrode 3, a dielectric container 4, and a nozzle 12. The electrode 3, which is completely covered by the dielectric material 5, is inserted into the dielectric container 4 and connected to the power supply 1 through a power controller 9. The dielectric material 5 is a coated dielectric layer and is fixed inside the dielectric container 4 with the hackle-sheet electrode 3 together as shown in the FIG. 11(b). The electrode 3 is in the shape of a hackle with a sharp top 3.1. The flow rate of the working gas 6 injected into the dielectric container 4 from the gas inlet 7 is adjusted by a flow controller 8. The plasma jet 10 is generated when the device operated.

FIG. 12(a) is an elevational view of a rectangle-sheet electrode, and FIG. 12(b) is a side-view of a rectangle-sheet electrode. The electrode has a sharp top 3.2, matching the nozzles in geometry of a racetrack (oblateness) to generate a sheet-shaped plasma jet.

FIGS. 13(a)-(b) are cross-sectional views of alternative embodiments of the nozzle having a circular cross-section and a racetrack-shaped cross-section, generated by electrodes arranged in a circle or a disk, and a sheet-shape, respectively. A large-scale and large-area plasma jets can be generated.

The electrode 3 is in form of a thread-like, a rod-like, or a sheet-like conductor having a certain geometry and size, or in the form of a sheet of conductive material coated onto the internal wall of a closed-end dielectric material 5, or in the form of a length of conductive material filled in the closed end of the dielectric material 5. The conductive material of the electrode 3 can be made tungsten, copper, aluminum, stainless steel, etc.

The working gas 6 used to power the plasma device is helium, oxygen, argon, nitrogen, air mixture gas, gaseous compounds, gaseous organic compounds, or mixtures thereof.

The dielectric material 5 and the dielectric container 4 is made of quartz glass, Plexiglas, or alumina. The shape and size of the dielectric material 5 and the dielectric container 4 are adjusted in accordance with the requirements of actual applications.

The distance between electrode 3 and the plasma jet outlet or nozzle is adjusted in a certain range in accordance with the requirements of actual applications.

The gas inlets 7 are located in the bottom or the side of the dielectric container 4, which enables the working gas 6 to be injected into the dielectric container 4 uniformly. The number and the position of the gas inlets are adjusted in accordance with the requirements of actual applications.

For example, helium is used the working gas 6, and the flow controller 8 is controlled to inject the working gas 6 into the dielectric container 4 through the gas inlet 7 with a flow rate of 2 L/min. When the applied voltage (alternating current) is adjusted to 5 kV with the frequency 38 kHz, high local electric field is induced in the discharge space in front of the top of the dielectric material 5, which including the internal space between the dielectric material 5 and the dielectric container 4 and the external space in front of the plasma jet outlet 11 or the nozzle 12. Accordingly plasma jet 10 is generated through the dielectric barrier discharge and the plasma jet 10 distributed in the internal space and the external space in front of the top of the dielectric material 5 extends into the surrounding air to a length of up to 110 mm. The temperature of the jet is close to room temperature and the jet can be contacted with human skin directly.

These embodiments described above include a nozzle 12 and a grounding electrode 16. The grounding electrode 16 is in the form of a filament-like ring or a sheet-like ring, made of tungsten, copper, aluminum, or stainless steel etc, and the position of the grounding electrode 16 can be adjusted in a certain range in accordance with the requirements of actual applications.

Among these embodiments above, the flow rate and the uniformity of the working gas 6 have an effect on the geometry and the length of the generated plasma jet 10. When the power supply 1 generates alternating current (AC), the range of the applied voltage and the frequency are 220 V-60 kV and 50 Hz-13.6 MHz, respectively. When the power supply 1 generates pulsed direct current power (Pulsed DC), the range of the applied voltage and the frequency are 220 V-50 kV and 50 Hz-100 MHz, respectively, having a pulse-width of more than 1 ns. The length of the generated plasma jet 10 is more than 0.1 mm.

The geometrical shape of the cross-section of the nozzle 12 is a circle, an ellipse, a racetrack-shape, a rectangle, a polygon or a combination thereof. The shape can be adjusted in accordance with the requirements of actual applications.

The core of the present invention lies in that the electrode is completely covered by the dielectric material, regardless of whether the dielectric material is a dielectric tube, a dielectric sheath, a coated dielectric layer, or any other material, regardless of the shape and the manner of arrangement of the electrodes inside the dielectric container, regardless of the shape of the nozzle and the plasma jet outlet, and regardless of the structure of the entire device. All such plasma jet devices are intended to be protected by the pendent claims as long as the electrode is covered completely by a dielectric material.

This invention is not to be limited to the specific embodiments disclosed herein and modifications for various applications and other embodiments are intended to be included within the scope of the appended claims. While this invention has been described in connection with particular examples thereof, the true scope of the invention should not be so limited since other modifications will become apparent to the skilled practitioner upon a study of the drawings, specification, and following claims.

All publications and patent applications mentioned in this specification are indicative of the level of skill of those skilled in the art to which this invention pertains. All publications and patent applications mentioned in this specification are herein incorporated by reference to the same extent as if each individual publication or patent application mentioned in this specification was specifically and individually indicated to be incorporated by reference.

What is claimed is:

1. A plasma jet device, comprising:
a dielectric container comprising a gas inlet and a plasma jet outlet; and
an electrode inserted into the dielectric container and connected to a power supply;
wherein
the electrode is completely covered by dielectric material.

2. The device of claim 1, wherein the dielectric material is a hollow tube with one end closed and another end opened, and the electrode is inserted into the hollow tube and connected to the power supply at the open end.

3. The device of claim 1, wherein the dielectric material is a coated dielectric layer, which covers the electrode completely except one end for connecting to the power supply.

4. The device of claim 1, wherein the dielectric material is a hollow sheath with one end closed and another end opened, and the electrode is inserted into the hollow sheathe and connected to the power supply from the open end.

5. The device of claim 1, wherein a grounding electrode is disposed downstream outside the dielectric container or the nozzle.

6. The device of claim 2, wherein a grounding electrode is disposed downstream outside the dielectric container or the nozzle.

7. The device of claim 3, wherein a grounding electrode is disposed downstream outside the dielectric container or the nozzle.

8. The device of claim 4, wherein a grounding electrode is disposed downstream outside the dielectric container or the nozzle.

9. The device of claim 1, wherein multiple electrodes are disposed inside the dielectric container.

10. The device of claim 2, wherein multiple electrodes are disposed inside the dielectric container.

11. The device of claim 3, wherein multiple electrodes are disposed inside the dielectric container.

12. The device of claim 4, wherein multiple electrodes are disposed inside the dielectric container.

13. The device of claim 9, wherein the multiple electrodes inside the dielectric container are arranged in a single row or in multiple rows.

14. The device of claim 9, wherein the multiple electrodes inside the dielectric container are arranged in the form of a circle.

15. The device of claim 9, wherein the multiple electrodes inside the dielectric container are arranged in form of a disk.

16. The device of claim 9, wherein the cross-section of the plasma jet outlet and the nozzle is in the shape of a circle, an ellipse, a racetrack-shape, a rectangle, a polygon, or a combination thereof.

17. The device of claim 1, wherein the electrode is in the shape of a thread, a rod, or a sheet.

18. The device of claim 2, wherein the electrode is in the shape of a thread, a rod, or a sheet.

19. The device of claim 3, wherein the electrode is in the shape of a thread, a rod, or a sheet.

20. The device of claim 4, wherein the electrode is in the shape of a thread, a rod, or a sheet.
